(19) United States
(12) Patent Application Publication
(10) Pub. No.: US 2010/0189926 A1
(43) Pub. Date: Jul. 29, 2010

(54) PLASMA DEPOSITION APPARATUS AND METHOD FOR MAKING HIGH PURITY SILICON

(76) Inventors: Charles DeLuca, South Windsor, CT (US); Evgueni Danilov, St. Petersburg (RU); Dau Wu, Fallbrook, CA (US); Peter T. Hansen, Jamestown, RI (US); Mohd Aslami, Sturbridge, MA (US)

Correspondence Address: PATTON BOGGS LLP, 2550 M STREET NW, WASHINGTON, DC, 20037-1350, US

(21) Appl. No.: 12/697,367

(22) Filed: Feb. 1, 2010

Related U.S. Application Data
(63) Continuation-in-part of application No. 12/081,337, filed on Apr. 15, 2008, now abandoned.
Application No. 12/081,337 is a continuation-in-part of application No. 11/786,969, filed on Apr. 13, 2007.
Application No. 12/081,337 is a continuation-in-part of application No. 11/783,969, filed on Apr. 13, 2007.
Application No. 11/783,969 is a continuation-in-part of application No. 11/714,223, filed on Mar. 6, 2007.
Application No. 11/714,223 is a continuation-in-part of application No. 11/644,870, filed on Dec. 26, 2006.
(60) Provisional application No. 60/791,883, filed on Apr. 14, 2006.
(60) Provisional application No. 60/815,575, filed on Jun. 22, 2006.
(60) Provisional application No. 60/791,883, filed on Apr. 14, 2006.
(60) Provisional application No. 60/815,575, filed on Jun. 22, 2006.
(60) Provisional application No. 60/818,966, filed on Jul. 7, 2006.

(51) Int. Cl. C23C 16/44; C23C 16/54

(52) U.S. Cl. 427/578; 118/723 R

(57) ABSTRACT

A plasma deposition apparatus for making high purity silicon, including a chamber for depositing said high purity silicon, the chamber including a top defining substantially an upper end of the chamber; one or more sides having an upper end and a lower end, the top substantially sealingly joining the upper end of the one or more sides; a base defining substantially a lower end of the chamber, the base substantially sealingly joining the lower end of the one or more sides; and at least one induction coupled plasma torch disposed in the top, the at least one induction coupled plasma torch oriented in a substantially vertical position producing a plasma flame downward from the top towards the base, the plasma flame defining a reaction zone for reacting one or more reactants to produce the high purity.

### CROSS-REFERENCES TO RELATED APPLICATIONS

The application is a continuation-in-part of prior U.S. patent application Ser. No. 12/081,337, filed Apr. 15, 2008, which is a continuation-in-part of both U.S. patent application Ser. No. 11/786,969 filed Apr. 13, 2007 and U.S. patent application Ser. No. 11/783,969, filed Apr. 13, 2007, both of which claim the benefit of U.S. Provisional Patent Application Nos. 60/791,883, filed Apr. 14, 2006 and 60/815,575, filed Jun. 22, 2006. This application is also continuation-in-part of prior U.S. patent application Ser. No. 11/714,223, filed Mar. 6, 2007, which claims the benefit of U.S. Provisional Patent Application No. 60/818,966, filed Jul. 7, 2006. This application is a continuation-in-part of prior U.S. patent application Ser. No. 11/644,870, filed Dec. 26, 2006, which claims the benefit of U.S. patent application Ser. No. 10/631,720, filed Aug. 1, 2003. The entireties of these applications are incorporated herein by reference.

### FIELD OF THE INVENTION

The present invention relates to an apparatus and process for making high purity silicon.

### Problem

As oil prices have continued to increase and other energy sources remain limited, there is increasing pressure on global warming from the emissions of burning fossil fuel. There is a need to find and use alternative energy sources, such as solar energy because it is free and does not generate carbon dioxide gas. To that end, many nations are increasing their investment in safe and reliable long-term sources of power, particularly “green” or “clean” energy sources. Nonetheless, while the solar cell, also known as a photovoltaic cell or modules, has been developed for many years, it had very limited usage because the cost of manufacturing these cells or modules is still high, making it difficult to compete with energy generated by fossil fuel.

Presently, the single crystal silicon solar cell has the best energy conversion efficiency, but it also has high manufacturing cost associated with it. Alternatively, polycrystalline silicon while it does not have the same high efficiency of a single crystal cell, it is much cheaper to produce. Therefore, it has the potential for low cost photovoltaic power generation. One known method for making a single crystal ingot is to use a floating zone method to reprocess a polycrystalline silicon rod. Another known method is the Czochralski method that uses a seed crystal to pull a melted silicon from a melting crucible filled with polycrystalline silicon nuggets.

In addition, some prior art processes of making polysilicon use chlorosilanes that are dissociated by resistance-heated filaments to produce silicon, which is then deposited inside a bell-jar reactor. It is commonly known to make a semiconductor grade silicon with trichlorosilane and then later recycle these chlorosilanes. Also, there have been many attempts using different raw materials to make polysilicon followed by re-processing these un-reacted chemicals. Nevertheless, these previous attempts do not have a high deposition rates.

Another attempt is to use a high pressure plasma with chlorosilane to make polycrystalline silicon, and then recycle the un-reacted chemicals. In this attempt, the deposition takes place on the inside wall of a substrate to form a sheet type silicon that will eventually be separated from the substrate, thus requiring additional process steps.

In addition, a commonly known process involves making a solar cell by (i) manufacturing polycrystalline silicon, (ii) making either a single crystal or a polycrystalline ingot or block, (iii) making wafers from the ingot or block, (iv) and then making a cell, that includes the step of p-type and n-type doping via a costly diffusion process. The p-type and n-type dopants form the p-n junction of the semiconductor material. This step is normally done in extremely slow diffusion furnaces after the thin-film layer has already been deposited, thus further slowing down the overall process of efficiently producing solar cells.

In addition, prior art methods have the deposition surface parallel to the plasma flame stream, thus the collection efficiency is much lower. The gaseous silicon hydrides are deposited using a high-frequency plasma chemical vapor deposition process to deposit silicon on a horizontal silicon core rod. Because of the orientation of the deposition apparatus, much of the silicon products are exhausted out of the apparatus.

Further known prior art methods for producing silicon create internal strain within the silicon rod. An attempt to reduce the internal stress follows the basic Siemens process and making the silicon rod in a bell-jar, where the process steps are: heating a silicon core material in a gaseous atmosphere including trichlorosilane and hydrogen to deposit silicon on the silicon core material to produce a polycrystalline silicon rod, heating the polycrystal silicon rod by applying an electric current without allowing the polycrystal silicon rod to contact with air so that the surface temperature of the polycrystal silicon rod is higher than the deposition reaction temperature of silicon and is 1,030° C. or higher, and shutting off the electric current after the heating by reducing the applied current as sharply as possible, thereby attempting to reduce the internal strain rate of the polycrystal silicon rod. As can be seen, this process involves a plurality of additional steps.

In another attempt to produce a polycrystalline silicon metal from a silicon halide plasma source, the silicon halide is split into silicon and halide ions in an inductively coupled plasma and silicon ions are then condensed to form molten silicon metal that can be vacuum cast into polysilicon ingots. In addition, the laden gases are fluorine and chlorine. Fluorine and hydrogen fluoride are highly corrosive, thus they require special corrosion resistant material for building the equipment and when handling these chemicals special case must be taken.

### Solution

The above-described problems are solved and a technical advance achieved by the present plasma deposition apparatus and method for making high purity silicon disclosed in this application.

In one embodiment, a plasma deposition apparatus for making high purity silicon, includes a chamber for depositing said high purity silicon, the chamber including a top defining substantially an upper end of the chamber; one or more sides having an upper end and a lower end, the top substantially sealingly joining the upper end of the one or more sides; a base defining substantially a lower end of the chamber, the base substantially sealingly joining the lower end of the one or more sides; and at least one induction coupled plasma torch disposed in the top, the at least one induction coupled plasma torch oriented in a substantially vertical position producing a plasma flame downward from the top towards the base, the plasma flame defining a reaction zone for reacting one or more reactants to produce the high purity silicon.

In one aspect, the base is a product collection reservoir for containing the high purity silicon in a liquid or molten state. In another aspect, the plasma deposition apparatus for making high purity silicon further includes one or more auxiliary gas injection ports disposed in the one or more sides for injecting auxiliary gases into the chamber. Preferably, the plasma deposition apparatus for making high purity silicon includes one or more vapor/gas removal ports disposed in the one or more sides for recovering at least one of un-deposited solids and un-reacted chemicals from the chamber.

In yet another aspect, the plasma deposition apparatus for making high purity silicon further includes a heater in thermodynamic communication with the base for providing heat to the base for keeping the high purity silicon in a liquid or molten state. Also, the at least one induction coupled plasma torch is substantially perpendicular to the base of the chamber. Preferably, the chamber is made from a material that shields RF energy and isolates the chamber from the environment outside of the chamber. The at least one induction coupled plasma torch may further include one or more zinc injection ports for injecting zinc into the plasma flame.

In another embodiment, a plasma deposition apparatus for making high purity silicon includes a chamber having an upper end and a lower end for depositing the high purity silicon in a liquid or molten state; a product collection reservoir disposed substantially in the lower end of the chamber for collecting the high purity silicon in a liquid or molten state; a heater in thermodynamic communication with the product collection reservoir for providing sufficient heat to the product collection reservoir to keep the high purity silicon in a liquid or molten state; and one or more induction coupled plasma torches disposed substantially in the upper end of the chamber, the one or more induction coupled plasma torches oriented in a substantially vertical position producing a plasma flame having a downward direction from the upper end of the chamber towards the product collection reservoir, the plasma flame defining a reaction zone for reacting one or more reactants to produce the high purity silicon.

In one aspect, the plasma deposition apparatus for making high purity silicon further includes one or more auxiliary gas injection ports disposed in the chamber for injecting auxiliary gases into the chamber. Also, the one or more auxiliary gas injection ports are disposed at a downward angle toward the product collection reservoir. Preferably, the plasma deposition apparatus for making high purity silicon, further includes one or more vapor/gas removal ports disposed in the chamber for recovering at least one of un-deposited solids and un-reacted chemicals from the chamber. In another aspect, the one or more vapor/gas removal ports are disposed at a downward angle toward the product collection reservoir. In yet another aspect, the one or more induction coupled plasma torches are substantially perpendicular to the product collection reservoir. Additionally, the chamber is made from a material that shields RF energy and isolates the chamber from the environment outside of the chamber. The one or more induction coupled plasma torches may further include one or more zinc injection ports for injecting zinc into the plasma flame.

In yet another embodiment, a method for collecting liquid or molten high purity silicon in a product collection reservoir in a reaction chamber includes providing the product collection reservoir; providing at least one vertically downwardly positioned high frequency induction coupled plasma torch comprising a coil; introducing a plasma gas consisting essentially of an inert gas into the high frequency induction coupled plasma torch to form a plasma within the coil; injecting reactants into the high frequency induction coupled plasma torch to produce a high purity silicon; and collecting the high purity silicon produced by the induction coupled plasma torch into the product collection reservoir.

In one aspect, the method for collecting liquid or molten high purity silicon in a product collection reservoir further includes adjusting the partial pressure within the chamber. Additionally, the method for collecting liquid or molten high purity silicon in a product collection reservoir further includes heating the product collection reservoir to keep the high purity silicon in a liquid or molten state. In another aspect, the method for collecting liquid or molten high purity silicon in a product collection reservoir further includes controlling the temperature of the product collection reservoir. Further, the method for collecting liquid or molten high purity silicon in a product collection reservoir may further include injecting auxiliary gases into the chamber. In yet another aspect, the method for collecting liquid or molten high purity silicon in a product collection reservoir further includes removing at least one of un-deposited solids and un-reacted chemicals from the chamber. In addition, the method may include introducing a supply of zinc into the high frequency induction coupled plasma torch.

In still yet another embodiment, a method for producing a silicon crystal, includes providing the product collection reservoir; providing at least one vertically downwardly positioned high frequency induction coupled plasma torch comprising a coil; introducing a plasma gas consisting essentially of an inert gas into the high frequency induction coupled plasma torch to form a plasma within the coil; injecting reactants into the high frequency induction coupled plasma torch to produce a high purity silicon; collecting the high purity silicon produced by the induction coupled plasma torch in a liquid or molten state into the product collection reservoir; and transferring the high purity silicon in a liquid or molten state to a crucible; and producing the silicon crystal or wafer.

In one aspect, the method for producing a silicon crystal further includes storing the high purity silicon in a liquid or molten state prior to transferring it to the crucible. In another aspect, the method for producing a silicon crystal further includes transferring the high purity silicon in a liquid or molten state in a conduit from the product collection reservoir to the crucible. Also, the method producing a silicon crystal further includes heating the conduit to keep the high purity silicon in a liquid or molten state. In addition, the method may include introducing a supply of zinc into the high frequency induction coupled plasma torch. Further, the silicon crystal may be a silicon wafer.

### BRIEF DESCRIPTION OF THE DRAWINGS

FIG. 1 illustrates a cross sectional view of a plasma deposition apparatus including a single induction coupled plasma torch for making high purity silicon according to an embodiment of the present invention;

FIG. 2 illustrates a cross sectional view of a plasma deposition apparatus including several induction coupled plasma torches according to another embodiment of the present invention;

FIG. 3 illustrates a cross sectional view of one of the downward positioned induction coupled plasma torches of FIGS. 1 and 2 according to an embodiment of the present invention;

FIG. 4 illustrates a cross sectional view of one of the downward positioned induction coupled plasma torches of FIGS. 1 and 2 according to an embodiment of the present invention;

FIG. 5 illustrates a block diagram of a system for making high purity silicon according to an embodiment of the present invention; and

FIG. 6 a flow diagram of a process for making high purity silicon according to an embodiment of the present invention

### DETAILED DESCRIPTION OF THE DRAWINGS

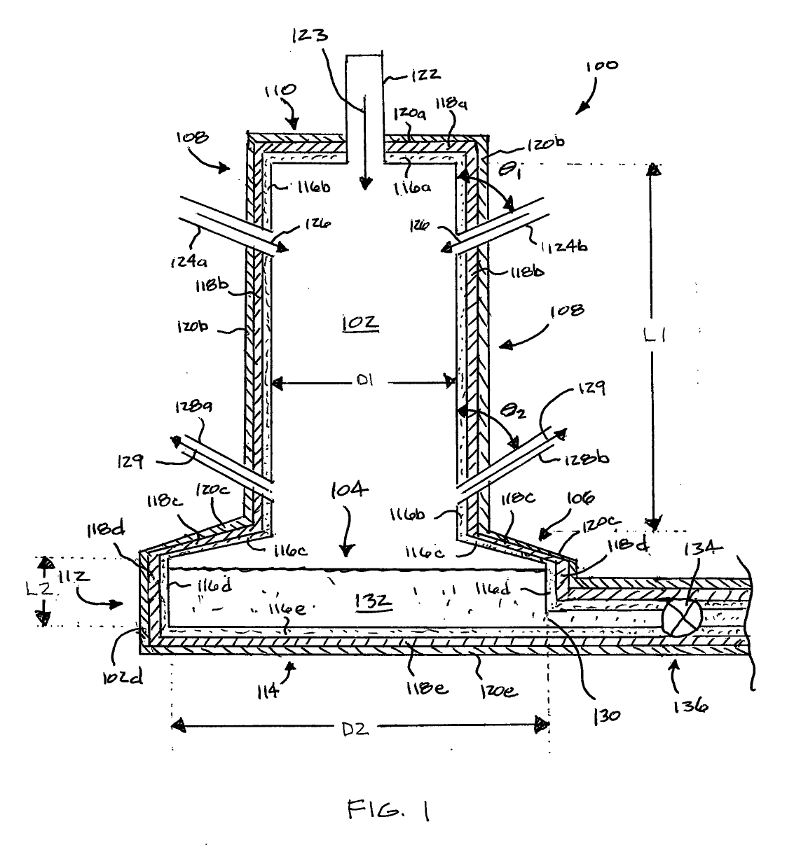

Referring to FIG. 1, an embodiment of a plasma deposition apparatus 100 is shown. Plasma deposition apparatus 100 includes a reaction chamber 102 and product collection reservoir 104 that are joined in a sealing relationship via a shoulder or flange 106. Reaction chamber 102 is formed by sides 108 and a top 110 that are preferably joined together in a sealing relationship. Additionally, product collection reservoir 104 in is formed by sides 112 and a bottom 114 that are also preferably formed in a sealing relationship. As described in detail below, product collection reservoir product collection reservoir 104 collects silicon in a molten or liquid form that is produced in reaction chamber 102.

Plasma deposition apparatus 100 may include inner surfaces or walls 116a-116e (collectively walls 116) that are preferably chemically inert to the reactants or products introduced into reaction chamber 102 and product collection reservoir 104. Additionally, plasma deposition apparatus 100 may include heating elements 118a-118e (collectively heating elements 118) that may be partially or completely adjacent to walls 116 to provide sufficient heat to walls 116 to keep the reactants and products within reaction chamber 102 and product collection reservoir 104 at a desired temperature, such as in a molten state. Additionally, plasma deposition apparatus 100 may include an outer shell 120a-120e (collectively outer shell 120) that may enclose walls 116 and heating elements 118.

In one embodiment, plasma deposition apparatus 100 may include all of walls 116 as shown in FIG. 1. In another embodiment, plasma deposition apparatus 100 may include portions of walls 116. In one example, plasma deposition apparatus 100 may not include wall 116a. For example, plasma deposition apparatus 100 may only include portions and not complete sections of walls 116b in reaction chamber 102. If walls 116 are independent sections of material, they may be joined together to form a continuous sealed wall or inner surface for reaction chamber 102 and product collection reservoir 104 of plasma deposition apparatus 100. Preferably, one or more of walls 116 are chemically inert to the reactants and products in reaction chamber 102. In one embodiment, one or more of walls 116 may be made of quartz or have a surface coated with quartz. In another embodiment, one or more of walls 116 may be made of carbon or have a surface coated with carbon. In one aspect, walls 116b, 116c, 116d, and 116e are made of quartz or have a surface coated with quartz. In another aspect, walls 116b, 116c, 116d, and 116e are made of carbon or have a surface coated with carbon. Additionally, if any of walls 116 are separate walls or panels, they may be joined together with adjacent walls by welding or other joining methods as known in the art. Additionally, they may be include glass leak-tight joints as known in the art.

In another embodiment, plasma deposition apparatus 100 may include all of heating elements 118 as shown in FIG. 1. In another embodiment, plasma deposition apparatus 100 may include some or a portion of heating elements 118. For example, plasma deposition apparatus 100 may not include heating element 118a. In another example, plasma deposition apparatus 100 may include portions and not complete sections of heating element 118b. In yet another example, plasma deposition apparatus 100 may not include heating element 118d. In one aspect the heating elements provide sufficient heat to reaction chamber 102 and product collection reservoir 104 that the high purity silicon product is collected in product collection reservoir 104 in a molten or liquid state. In one aspect, heating elements 118 provide a temperature of approximately 1,000° C. in reaction chamber 102. Further, in another aspect, heating elements 118 provide a temperature of approximately 1,450° C. or higher in product collection reservoir 104.

Further, plasma deposition apparatus 100 may include all of outer shell 120 as shown in FIG. 1. In another embodiment, plasma deposition apparatus 100 may include some or a portion of outer shell 120. For example, plasma deposition apparatus 100 may not include outer shell 120c. In another embodiment, plasma deposition apparatus 100 may include portions and not complete sections of outer shell 120b. In yet another example, plasma deposition apparatus 100 may not include outer shell 120e. In one aspect, outer shell 120 is made of a material that is resistant to the elements outside of plasma deposition apparatus 100. In one example, outer shell 120 is made from stainless steel.

In addition, plasma deposition apparatus 100 includes an induction coupled plasma torch 122 that is disposed in reaction chamber 102 in a substantially downward vertical orientation relative to reaction chamber 102. The flow of plasma torch gases, reactants, and products is generally shown as arrow 123. Induction coupled plasma torch 102 is in communication with reaction chamber 104. Plasma deposition apparatus 100 may further include one or more auxiliary gas injection ports 124a-124b (collectively 124) that are substantially located or disposed in sides 108 of plasma deposition apparatus 100 and in communication with reaction chamber 102 for injecting auxiliary gases 126 into reaction chamber 102. In one embodiment, auxiliary gases 126 may be Hydrogen or Hydrogen mixed with Argon. Also, the flow rate of auxiliary gases 126 may be from about 5 standard liters per minute (SLPM″) to about 400 SLPM, depending on the process design.

Preferably, both plasma deposition apparatus 100 and plasma deposition apparatus 200, as described below, may include any number of auxiliary gas injection ports 124. In one embodiment, it is preferable to arrange auxiliary gas injection ports 124 so that they are symmetrical relative to the center line of reaction chamber 102. For example, if plasma deposition apparatus 100 or plasma deposition apparatus 200 include four auxiliary gas injection ports 124, then it would be preferable to have them each directed towards the center line of reaction chamber 102 at 90° spacing intervals. Further, it is preferable that auxiliary gas injection ports 124 are located nearer to the top of reaction chamber 102. In one embodiment, auxiliary gas injection ports 124 are located or disposed from about 20 millimeters (“mm”) to about 30 mm down from the top of walls 116b of reaction chamber 102. Additionally, they may be angled relative to the vertical center line of reaction chamber 102. For example, an angle θ₁ is formed between auxiliary gas injection ports 124 and walls 116b. In one embodiment, angle θ₁ is from about 30° to about 60°. Preferably, auxiliary gas injection ports 124 are made of quartz and have an inner diameter of approximately 6 mm and a wall thickness of approximately 1.5 mm.

Plasma deposition apparatus 100 further includes one or more vapor/gas removal ports 128a-128b (collectively 128) that are located or disposed lower on sides 108 than auxiliary gas injection ports 124 of plasma deposition apparatus 100, in one example. Vapor/gas removal ports 124 may remove any unreacted exhaust gases 129 from plasma deposition apparatuses 100 and 200, as described below, for later recycling. Additionally, plasma deposition apparatuses 100 and 200 may include recycling, separation, and drying units in communication with vapor/gas removal ports 124 for separating exhaust gases 129 from other exhaust gases for recycling back into auxiliary gas injection ports 124.

Preferably, the exhaust system (not shown) controls or maintains a fixed partial pressure inside reaction chambers 102 and 202 to ensure an optimum reaction conditions for the reactants. The control of the partial pressure within reaction chambers 102 and 202 may further include providing a negative pressure, such as a vacuum. In another embodiment, the partial pressure may be controlled at or near atmospheric pressure. Any number of vapor/gas removal ports 128 may be employed as desired for a specific application. Preferably, reaction chambers 102 and 202 may be made of an explosive proof material and RF shield material for preventing escape of RF energy from reaction chambers 102 and 202 and for isolating the environmental influences upon reaction chambers 102 and 202.

Vapor/gas removal ports 128 may be made of quartz tubing and may have an inner diameter of approximately 50 mm and a wall thickness of approximately 2.5 mm. In one embodiment, it is preferable to arrange vapor/gas removal ports 128 so that they are symmetrical relative to the center line of reaction chamber 102. For example, if plasma deposition apparatus 100 or plasma deposition apparatus 200 include four vapor/gas removal ports 128, then it would be preferable to have them each directed towards the center line of reaction chamber 102 at 90° spacing intervals. Further, it is preferable that vapor/gas removal ports 128 are located nearer to the bottom of reaction chamber 102. In one embodiment, vapor/gas removal ports 128 are located or disposed from about 30 mm to about 50 mm up from the top of product collection reservoir 104.

Additionally, they may be angled relative to the vertical center line of reaction chamber 102. For example, an angle θ₂ is formed between vapor/gas removal ports 128 and walls 116b. In one embodiment, angle θ₂ is from about 15° to about 30°. The angled vapor/gas removal ports 128 will prevent small silicon particles from escaping with exhaust gases 129.

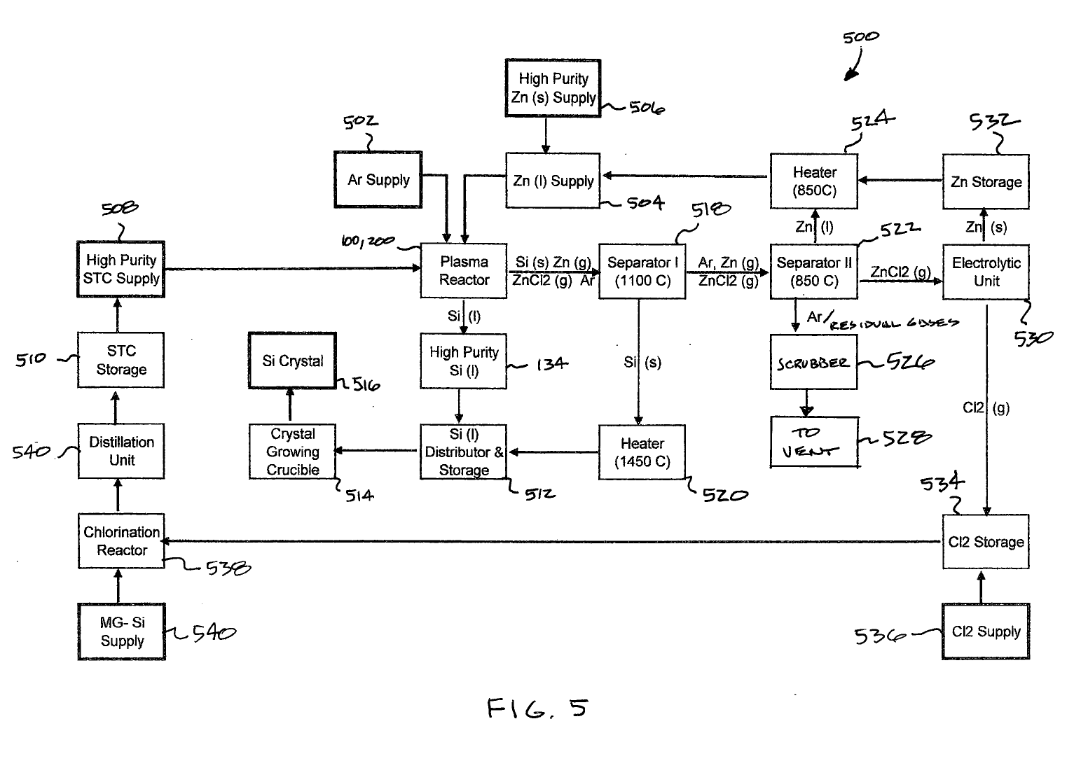

Additionally, plasma deposition apparatus 100 includes an opening 130 in product collection reservoir 104 that feeds liquid or molten silicon 132 via a valve 134 and a conduit or pipe 136 to a distribution valve or manifold and/or storage vessel 514 (FIG. 5). In one aspect, pipe 136 includes heating elements and possibly shells as discussed above to keep silicon 132 in a molten state.

Any of top 110, sides 108, sides 112, or bottom 114 of plasma deposition apparatus 100 may be of any geometric shape or size. For the purposes of discussion and not to be limited in any way, the following description of plasma deposition apparatus 100 being of a generally cylindrical shape is provided. In one embodiment, as shown in FIG. 1, reaction chamber 102 may be substantially cylindrically-shaped as shown in the cross-sectional view. In this embodiment, reaction chamber 102 may be a quartz tube with an inner diameter (“D1”) of approximately 150 mm. Preferably, the thickness of walls 116b is approximately 3 mm with a length (“L1”) of approximately 1,000 mm. A product collection reservoir 104 of plasma deposition apparatus 100 may also be a quartz tube with an inner diameter (“D2”) of approximately 250 mm. Preferably, the thickness of walls 116d is approximately 5 mm and the length (“L2”) of approximately 500 mm.

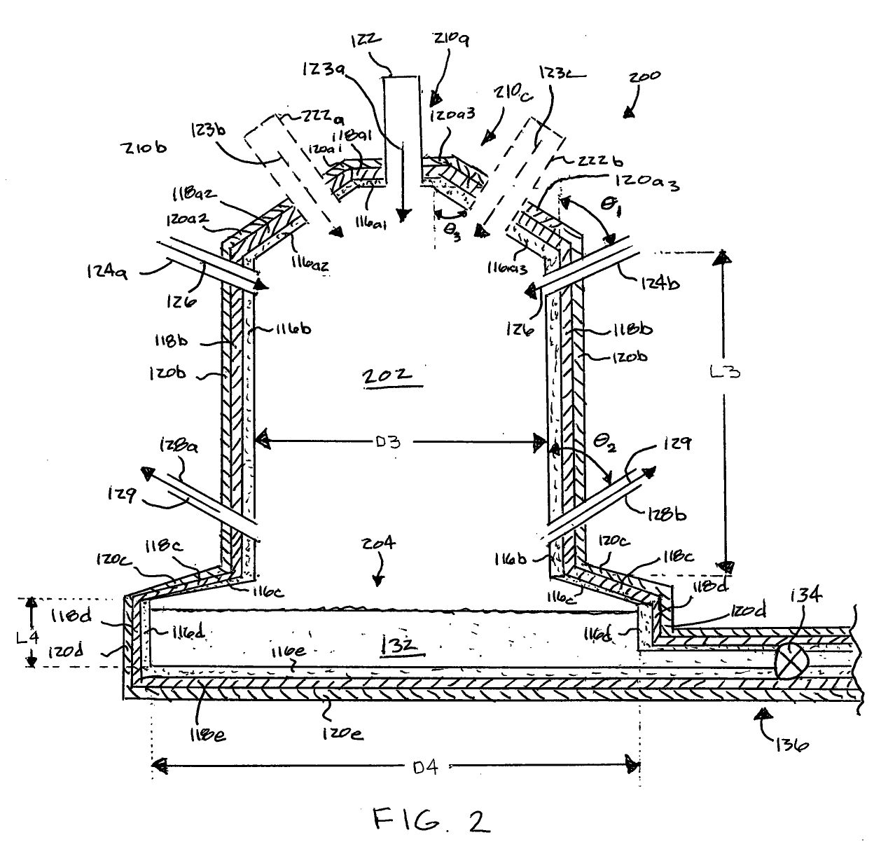

Referring now to FIG. 2, another embodiment 200 of plasma deposition apparatus is shown. Plasma deposition apparatus 200 includes many of the same components as discussed above relative to plasma deposition apparatus 100, thus the same numbered elements refer to those components discussed above relative to plasma deposition apparatus 100. The actual dimensions or number of these common components may or may not be the same between plasma deposition apparatuses 100 and 200. In general, the main difference between plasma deposition apparatus 100 and plasma deposition apparatus 200 is the size of plasma deposition apparatus 200 is larger than plasma deposition apparatus 100 to accommodate multiple induction coupled plasma torches.

Plasma deposition apparatus 200 includes a flat top portion 210a and two angled top portions, 210b and 210c (collectively top 210). The sloping or angling of tops 210b and 210c relative to top 210a is to direct or aim the products discharged from induction coupled plasma torch 122 and induction coupled plasma torches 222b and 222c (collectively 222) toward the center of reaction chamber 102 and away from walls 116b. The flow of plasma torch gases, reactants, and products is generally shown as arrow 123b and 123c. This further helps with preventing the products from sticking or accumulating on the sides of walls 116b, which decreases unnecessary build-up of products on the sides of walls 116b thereby improving product yield.

In this embodiment, a reaction chamber 202 of plasma deposition apparatus 200 may be a quartz tube with an inner diameter (“D3”) of approximately 320 mm. Preferably, the thickness of walls 116b is approximately 5 mm and the length (“L3”) of approximately 1,000 mm. A product collection reservoir 204 of plasma deposition apparatus 200 may also be a quartz tube with an inner diameter (“D4”) of approximately 400 mm. Preferably the thickness of walls 116d is approximately 6 mm and the length (“L4”) of approximately 600 mm. In one embodiment, flange 106 is a disk of quartz that has a thickness of approximately 6 mm. Preferably, the inner diameter of the flange 106 equals approximately the inner diameter D3 of reaction chamber 102 and the outer diameter of flange 106 equals approximately the inner diameter D4 of product collection reservoir 104. Silicon 132 in a liquid or molten state is then ultimately fed to crystal growing crucibles or the like for growing silicon crystals, as further described below. Preferably, the thickness of walls 116a1, 116a2, and 116a3 is approximately 3 mm. In one embodiment, wall 116a1 is a disk of quartz that has an outer diameter of approximately 80 mm. Additionally, an angle θ₃ is formed between top 210a and 210b, and top 210a and 210c. This angle θ₃ when measured between a perpendicular vertical line extending downward from top 210a and the inner planar surfaces of each of tops 210b and 210c is from about 45° to about 60°. Preferably, auxiliary gas injection ports 124 are made of quartz and have an inner diameter of approximately 6 mm and a wall thickness of approximately 1.5 mm.

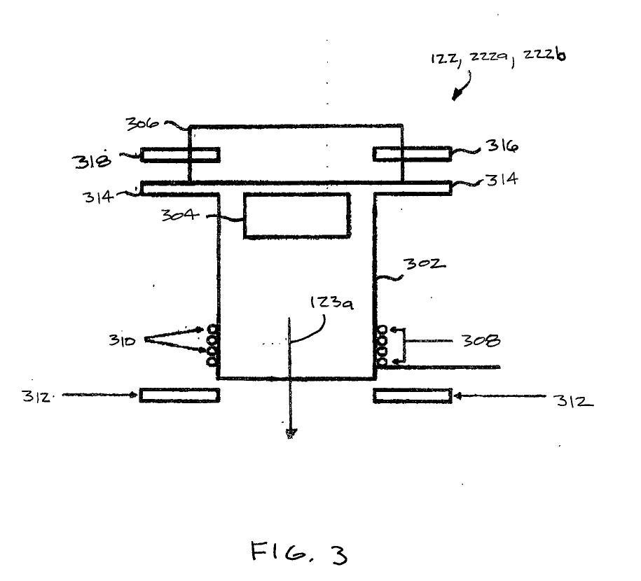

Referring to FIG. 3, a side view of induction coupled plasma torch 122 is shown. The following discussion may also apply to induction coupled plasma torches 222a and/or 222b. In this embodiment, induction coupled plasma torch 122 is aimed downward for depositing silicon 132 in product collection reservoir 104. Induction coupled plasma torch 122 consists of two concentric quartz tubes: an outer quartz tube 302 and a shorter inner quartz tube 304, which are shown to be attached to a stainless steel chamber 306.

Typically, the diameter and height or length of outer quartz tube 302 and inner quartz tube 304 may be any size to fit the desired application of outer quartz tube 302 and inner quartz tube 304. Preferably, inner quartz tube 304 has a shorter length than outer quartz tube 302. Also, outer quartz tube 302 preferably has a diameter in the range of from about 50 mm to about 90 mm and a height in the range of from 180 mm to about 400 mm. More preferably, the diameter for outer quartz tube 302 is about 70 mm with a height or length of about 250 mm. Preferably, inner quartz tube 304 has a diameter in the range of from about 50 mm to about 70 mm and a height in the range of from about 120 mm to about 180 mm. More preferably, the diameter of inner quartz tube 304 is about 60 mm with a height of about 150 mm.

Induction coupled plasma torch 122 includes a coil 308 that is located around the lower portion of the outer quartz tube 302. Coil 308 comprises a plurality of windings 310 having a diameter of approximately in the range of from about 56 mm to about 96 mm. Preferably, the plurality of windings 310 has a diameter of about 82 mm. Typically, the plurality of windings 310 are spaced apart from each other by a sufficient distance to provide for operation of induction coupled plasma torch 122. Preferably, the plurality of windings 310 are spaced apart from each other by about 6 mm. In addition, a gap between outer quartz tube 302 and coil 308 can be in a range of from about 2 mm to about 10 mm.

Induction coupled plasma torch 122 further includes a pair of injection ports 312 that are connected to a precursor source chemical line (not shown) carrying the precursor source chemicals to induction coupled plasma torch 122. The source chemicals for deposition of semiconductor material such as silicon 132 will be injected through injection ports 312, which are preferably located near the lower side of induction coupled plasma torch 122 and aimed toward the V=0 position for the same reason as disclosed in U.S. Pat. No. 6,253,580 issued to Gouskov et al. and U.S. Pat. No. 6,536,240 issued to Gouskov et al, both of which are incorporated herein by reference. In one embodiment, injection ports 312 are connected to induction coupled plasma torch 122, at the lower end of outer quartz tube 302. In one embodiment, induction coupled plasma torch 122 is an inductively coupled plasma torch. Injection ports 312 comprise quartz tubing preferably having a diameter in the range of from about 3 mm to about 10 mm, more preferably of about 5 mm, although tubing diameters in other sizes may be used with induction coupled plasma torch 122. In this embodiment, a pair of injection ports 312 is positioned diametrically across from each other. In another embodiment of the present invention, three or more injection ports 312, symmetrically arranged, may be utilized. In yet another embodiment, one injection port 312 may be positioned at the center of outer quartz tube 302 and above top coil 308. In this embodiment, injection port 312 may be disposed through the center of chamber 306.

Further, induction coupled plasma torch 122 includes a pair of plasma gas inlets 314 that are connected to a plasma gas supply line (not shown) carrying plasma gases to induction coupled plasma torch 122. Plasma gas inlets 314 enter induction coupled plasma torch 122 at substantially the same height. Preferably, plasma gas inlets 314 comprise stainless steel tubing having a diameter of 5 mm, although a range of diameters may suffice for this purpose. With the use of inner quartz tube 304 and outer quartz tube 302, the plasma source gas will have a swirl flow pattern.

Induction coupled plasma torch 122 is also provided with a coolant inlet 316 and coolant outlet 318. During use, a coolant, such as water, passes through coolant inlet 316, circulates within stainless steel chamber 306, and exits through coolant outlet 308. Coolant inlet 316 and coolant outlet 318 are preferably formed from stainless steel and have a diameter of 5 mm, for example.

Plasma gas inlets 314, coolant inlet 316, and coolant outlet 318 are all preferably formed in a stainless steel chamber 306. Chamber 306 is preferably a stainless steel square block 80 mm on a side, and having a height of approximately 40 mm, for example. Preferably, chamber 306 is mounted onto the support stand (not shown).

A high frequency generator (not shown) is electrically connected to coil 308, powering it with a variable power output up to 144 kW at a frequency of 2.0-4.0 MHz. In an embodiment, the generator is Model No. IG outer shell 120/3000, available from Fritz Huettinger Electronic GmbH of Germany. Preferably, this generator is driven with a 60 Hz, 3-phase, 480 V power supply to energize induction coupled plasma torch 122.

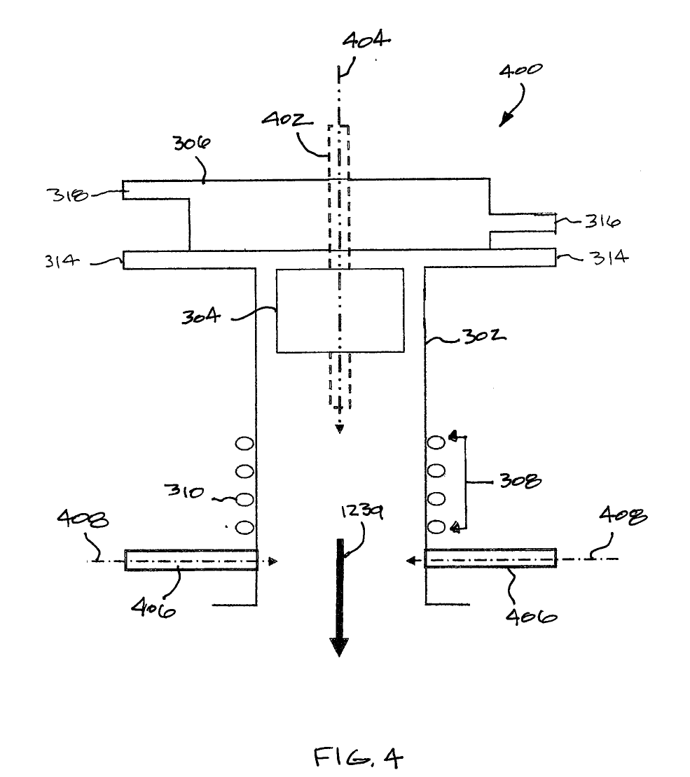

Referring now to FIG. 4, an induction coupled plasma torch according to another embodiment 400 is shown. Induction coupled plasma torch 400 may be used for producing silicon 132 in plasma deposition apparatuses 100 and/200. Similar reference numerals in induction coupled plasma torch 400 correspond to those elements and descriptions herein relative to induction coupled plasma torches 122, 222a, 222b.

In this embodiment, induction coupled plasma torch 400 may be used with Zinc replacing Hydrogen as the reducing agent for the silicone compound reactant, such as silicon tetrachloride (SiCl₄). The formula for such a reduction is:

SiCl₄+2 Zn→Si+2 ZnCl₂ Formula I

Induction coupled plasma torch 400 may include an injection port 402 for flowing a source of liquid (preferred) Zinc 404 through injection port 402 to induction coupled plasma torch 400. In another aspect, a source of Zinc 404 may be in a solid form, such as small particles of Zinc. In one aspect, injection port 402 is disposed and extends through the central part of chamber 306 and induction coupled plasma torch 400. Preferably, one end of injection port 402 is connected to a source of Zinc 404 and the other end of injection port 402 ends approximately 30 mm above the highest winding 310 of coil 308.

Additionally, induction coupled plasma torch 400 may include one or more injection ports 406 for injecting a source of silicon compound 408, such as SiCl₄, into induction coupled plasma torch 400. In one aspect, source of silicon compound 408 is in a vapor form. In one embodiment, injection ports 406 are disposed in induction coupled plasma torch 400 approximately 15 mm below the lowest windings 310 of coil 308.

Referring now to FIG. 5, a block diagram of a system for making high purity silicon according to an embodiment 500 of the present invention is shown. Without limiting the present system for making high purity silicon 500, the following description is presented relative to using Zinc as the reducing agent instead of Hydrogen. In this embodiment, plasma deposition apparatus 100 and/or plasma deposition apparatus 200 may utilize induction coupled plasma torch 400 for producing liquid or molten Zinc. Preferably, system for making high purity silicon 500 includes a source of Argon 502 that is in communication with and fed into plasma gas inlets 314 of induction coupled plasma torch 400 of reaction chambers 102, 202 of plasma deposition apparatuses 100, 200. Additionally, system for making high purity silicon 500 includes a source of Zinc 504 that is also in communication with plasma deposition apparatuses 100, 200. In one aspect, source of Zinc 504 may feed into injection port injection port 402 of induction coupled plasma torch 400. An additional supply of Zinc 506 may feed directly into source of Zinc 504 to provide additional Zinc to system for making high purity silicon 500. In one aspect, the Zinc contained in supply of Zinc 506 and source of Zinc 504 may be in a liquid state. Further, system for making high purity silicon 500 includes a source of silicon compound 508 that is in communication with and feeds into injection ports 406 of induction coupled plasma torch 400.

The high purity silicon 132 in a liquid or molten state produced by system for making high purity silicon 500 is then fed through valve 134 to a distribution/storage unit 512. The liquid or molten silicon 132 is then fed from distribution/storage unit 512 to a crystal growing crucible 514 to grow high purity silicon crystals 516. In one embodiment, the standard Czochralski (“CZ”) method can be used for growing a single or multiple silicon crystals 516. Also, the Edge-defined Film-fed Growth (“EFG”) method is another method to make Silicon wafers for photovoltaic applications.

Referring back to FIG. 5, exhaust gases 129 from plasma deposition apparatuses 100, 200 are removed from reaction chamber 102, 202 via vapor/gas removal ports 128 and fed to a first separator 518. In one aspect, exhaust gases 129 may include Argon gas, the by-product ZnCl₂, and any unreacted Zinc, which are in vapor form. Additionally, exhaust gases 129 may include small particles of Silicon. Separator 518 may be maintained at a temperature of approximately 1,100° C. Preferably, the vapor velocity through separator 518 may be reduced significantly, such that these small Silicon particles will drop to the bottom of separator 518 to be collected and fed into a heater 520. Heater 520 may be kept at a temperature of approximately 1,450° C. to melt the Silicon particles into a liquid or molten state, which can then be fed into distribution/storage unit 512.

System for making high purity silicon 500 may further include a second separator 522 that is in communication with separator 518 for feeding exhaust gases 129 from separator 518 to separator 522. Preferably, separator 522 may be kept at a temperature of approximately 850° C. The un-reacted Zinc contained in exhaust gases 129 will condense in separator 522 where it can be transferred or fed to a heater 524 that is preferably kept at a temperature of approximately 850° C. From heater 524, Zinc can be transferred or fed to source of Zinc 504 to be re-used in induction coupled plasma torch 400.

In one aspect, the remaining components in separator 522 may include ZnCl₂, Argon, and some residual gases. The Argon and residual gases may be treated in a scrubber 526 before being fed to a vent 528 that will release them to the atmosphere. In another aspect, Argon gas contained in separator 522 may be recycled and fed back into induction coupled plasma torch 400. Any unreacted or reacted Zinc compounds, such as ZnCl₂ is transferred from separator 522 to electrolytic unit 530, which will decompose the Zinc compound into Zinc and Cl₂ gas. Available processes for such decomposition are known to those skilled in the art. The produced Zinc may be transferred or fed back into induction plasma deposition apparatuses 100, 200 for reuse via Zinc storage unit 532, which may further feed heater 524 and source of Zinc 504.

Additionally, the Cl₂ gas produced by electrolytic unit 530 may be transferred or fed to Cl₂ storage unit 534. System for making high purity silicon 500 may include an additional supply of Cl₂ gas that is in communication with C12 storage unit 534. C12 storage unit 534 may supply Cl₂ to a chlorination reactor 538 where it may react with a supply of Metallurgical-Grade Silicon (“MG-Si”) to make additional Silicon containing compounds, such as SiCl₄. These compounds are transferred or fed from chlorination reactor 538 to a silicon compound storage unit 540 to purify the silicon compound to make a high purity silicon compound. System for making high purity silicon 500 further may include a silicon compound storage unit 510 that is in communication with source of silicon compound 508. Generally, silicon compound storage unit 510 is supplied a source of silicon compound from a silicon compound storage unit 540.

In addition to the aforementioned aspects and embodiments of the present plasma deposition apparatuses 100, 200, the present invention further includes methods for manufacturing liquid or molten silicon 132 and silicon crystals for use making photovoltaic cells. One preferred method includes a chloride based system that utilizes the plasma flame or energy to reduce trichlorosilane (“SiHCl₃”) by hydrogen (“H₂”) to form silicon. It can also reduce silicon tetrachloride (“SiCl₄”) with hydrogen by the plasma flame energy to make silicon. Generally, the silicon particles generated by plasma deposition apparatuses 100, 200 are small in size, such as a few microns. Under temperature control and continuing reaction of the reactants, the silicon particles travel down reaction chambers 102, 202 the size of the silicon particles may increase in size. These larger silicon particles will be easier to collect in product collection reservoirs 104, 204, which will improve the collection efficiency of plasma deposition apparatuses 100, 200.

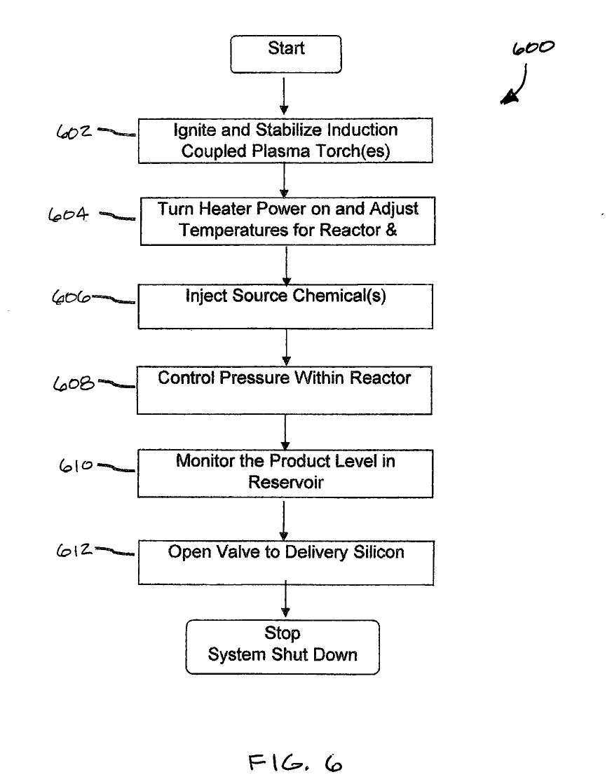

FIG. 6 illustrates a flow diagram of an embodiment 600 of a method for making high purity silicon. In step 602, induction coupled plasma torch 122, 222a, 222b, and 400 are initiated. This step can include initiating the flow of the plasma gas supply to plasma gas inlets 314 and then plasma ignition by supplying electricity to coil 308. This step includes igniting and stabilizing the plasma flame of induction coupled plasma torch 122, 222a, 222b, and 400. In addition, step 602 may also include selecting the precursor gas source to be used to produce the desired reaction product during production of silicon 132 on product collection reservoir 104.

In step 604, power to heating elements 118 is turned on and adjusted to the designated temperature for heating reaction chamber 102, product collection reservoir 104, reaction chamber 202, and product collection reservoir 204. In one embodiment, the temperature within reaction chambers 102, 202 is approximately 1,000° C. In step 606, plasma deposition apparatuses 100, 200 inject precursor gas through injection ports 312 to the plasma flame of induction coupled plasma torch 122, 222a, 222b, and 400. As discussed above, preferably the precursor gas source is selected from SiCl₃ plus H₂, SiCl₄ plus H2, or SiCl₄ plus Zinc.

As described above, the products that are not deposited on product collection reservoirs 104, 204 are collected through vapor/gas removal ports 128 and recycled for additional use. In one aspect of the present method for making high purity silicon, the SiHCl₃ and SiCl₄ can be made from MG-Si or Silica. MG-Si will react with Hydrogen Chloride (“HCl”) that is collected and separated from the exhaust gas stream of the present process for making high purity silicon. In addition, it is always possible to add fresh Chlorine (“Cl₂”) or HCl, if sufficient quantities do not exist from the exhaust stream. After purification by distillation, reaction products can be used as precursor source gas chemicals for making silicon.

In addition to HCl in the exhaust stream, there are Ar, H₂, dichlorosilane (“SiH₂Cl₂”), and un-reacted SiHCl₃ and SiCl₄ plus the un-deposited silicon particles may also exist. The un-deposited silicon particles can be separated out by using a bag filter. Further, using a cold trip, chlorosilanes can be easily separated and reused as precursor source gas chemicals. The gases such as Ar and H₂ can also be recycled from the exhaust system and can be used for plasma source gas or precursor source gas.

In step 608, the pressure within reaction chambers 102, 202 is controlled and maintained by the exhaust system and/or vapor/gas removal ports 128. In addition, other means may be employed to maintain the pressure within reaction chambers 102, 202. In step 610, the product level in product collection reservoirs 104, 204 is monitored. When the level is above a designated level, valve 134 opens in step 612 and the liquid or molten silicon 132 will be drained out to distribution/storage unit 512. Step 612 will also be activated when the crucible 514 requires additional silicon 132.

In one embodiment, method for making high purity silicon 600 is a continuous process where the plasma process will continue to operate until the scheduled maintenance. At that time, induction coupled plasma torch 122, 222a, 222b, and 400 will be shut down and the operation may be stopped.

In addition to the above, the silicon particles will be separated out from the exhaust stream. These particles will be collected, loaded into a quartz crucible, melted and grow into single crystal ingots. All the gases whether un-reacted or by-products chemicals will also be collected and separated by typical industry processes. Some exemplary raw materials include hydrides, fluorides, chlorides, bromides, and argon gas.

In another embodiment of the present method for making high purity silicon, a hydride based system is employed. Silane does not have high deposition rate as trichlorosilane, but it is still widely used in the industry, because it is much easier to purify and also to produce desired high quality silicon. Following the same processing steps above, Silane (“SiH₄”) or Disilane (“Si₂H₆”) in the gas form can be delivered to injection ports 312 as stated in step 604 and in the presence of the plasma flame or energy they will dissociate into silicon and hydrogen. By using a higher reaction temperature and removal of hydrogen gas quickly improved chemical reaction conversion is achieved. In addition, the un-deposited silicon particles and plasma source gas, such as Argon, are collected through vapor/gas removal ports 128 for re-processing and recycling.

In another embodiment of the present methods for making high purity silicon, a bromine system is employed following the process steps described above. Both bromine (“Br₂”) is chemically less aggressive and also less corrosive than chlorine (“Cl₂”). When using Br as a laden gas, a significant equipment costs can be saved. The laden gas is used as a transporting agent to bring, convert, and make the silicon (metallurgical grade silicon, MG-Si) into pure and useable solar grade silicon (“SoG”). It will react with the MG-Si to form Silicon Bromide (main product) and other impurities bromide compounds. After purification, Silicon Bromide is used for making high purity silicon by plasma process. During the process, it decomposes the Silicon Bromide into silicon and bromine. The silicon is deposited and bromine is also collected and reused again. Because the present induction coupled plasma torch 122, 222a, 222b, and 400 have more than enough energy to drive the reaction in the desirable direction, it will not be a concern for the reduction reaction of silicon tetrabromide (“SiBr₄”) by hydrogen. Preferably, the raw material for this system will be MG-Si. At temperatures higher than 360° C., the reaction rate between Silicon and hydrogen bromide (“HBr”) or Br, can be high and the reaction product will be mainly SiBr₄. Due to the differences in boiling temperatures, it is very easy to separate out the Boron contamination (BBr₃ from SiBr₄). In this embodiment, the precursor source gas chemicals will be Silicon tetrabromide and Hydrogen.

In yet another embodiment of the present methods for making high purity silicon, a reduction of silica soot particles by carbon is employed. In optical preform production, the solid waste is the silica soot particles and they usually are sent to a landfill for disposal. These silica soot particles are very pure and can be a good source for making Solar Grade Silicon (“SoG”) by the carbothermic reduction reaction with carbon. Typically, it uses an electric arc furnace as a heat source and following the process steps described above, a powder form of SiO₂ and carbon are injected through the injection ports 312 into the plasma flames of induction coupled plasma torch 122, 222a, 222b, and 400. These soot particles from preform manufacturers do not typically contain transition metal ions and also they do not typically contain boron. Nevertheless, the soot particles may have trace amount of phosphorous and some germanium. To eliminate the possible impurity contamination from the raw materials, small amount of Cl₂ and moisture can be injected with the precursor gas source. This embodiment converts the soot particle waste from optical fiber manufacturing plant into a useful product for producing high purity silicon, and thus generating efficient and cost effective solar panels.

Although there has been described what is at present considered to be the preferred embodiments of the plasma deposition apparatus and methods for making high purity silicon, it will be understood that the present plasma deposition apparatus can be embodied in other specific forms without departing from the spirit or essential characteristics thereof. For example, additional induction coupled plasma torches or different combinations of deposition modules, other than those described herein could be used without departing from the spirit or essential characteristics of the present plasma deposition apparatus and methods for making high purity silicon. The present embodiments are, therefore, to be considered in all aspects as illustrative and not restrictive. The scope of the invention is indicated by the appended claims rather than the foregoing description.

What is claimed:

1. A plasma deposition apparatus for making high purity silicon, comprising:
a chamber for depositing said high purity silicon, the chamber comprising:
a top defining substantially an upper end of the chamber;
one or more sides having an upper end and a lower end, the top substantially sealingly joining the upper end of the one or more sides;
a base defining substantially a lower end of the chamber, the base substantially sealingly joining the lower end of the one or more sides; and
at least one induction coupled plasma torch disposed in the top, the at least one induction coupled plasma torch oriented in a substantially vertical position producing a plasma flame downward from the top towards the base, the plasma flame defining a reaction zone for reacting one or more reactants to produce the high purity silicon.

2. The plasma deposition apparatus for making high purity silicon according to claim 1, wherein the base is a product collection reservoir for containing the high purity silicon in a liquid or molten state.

3. The plasma deposition apparatus for making high purity silicon according to claim 1, further comprising:
one or more auxiliary gas injection ports disposed in the one or more sides for injecting auxiliary gases into the chamber.

4. The plasma deposition apparatus for making high purity silicon according to claim 1, further comprising:
one or more vapor/gas removal ports disposed in the one or more sides for recovering at least one of un-deposited solids and un-reacted chemicals from the chamber.

5. The plasma deposition apparatus for making high purity silicon according to claim 1, further comprising:
a heater in thermodynamic communication with the base for providing heat to the base for keeping the high purity silicon in a liquid or molten state.

6. The plasma deposition apparatus for making high purity silicon according to claim 1, wherein the at least one induction coupled plasma torch is substantially perpendicular to the base of the chamber.

7. The plasma deposition apparatus for making high purity silicon according to claim 1, wherein the chamber is made from a material that shields RF energy and isolates the chamber from the environment outside of the chamber.

8. The plasma deposition apparatus for making high purity silicon according to claim 1, wherein the at least one induction coupled plasma torch further comprises:
one or more zinc injection ports for injecting zinc into the plasma flame.

9. A plasma deposition apparatus for making high purity silicon, comprising:
a chamber having an upper end and a lower end for depositing the high purity silicon in a liquid or molten state;
a product collection reservoir disposed substantially in the lower end of the chamber for collecting the high purity silicon in a liquid or molten state;
a heater in thermodynamic communication with the product collection reservoir for providing sufficient heat to the product collection reservoir to keep the high purity silicon in a liquid or molten state; and
one or more induction coupled plasma torches disposed substantially in the upper end of the chamber, the one or more induction coupled plasma torches oriented in a substantially vertical position producing a plasma flame having a downward direction from the upper end of the chamber towards the product collection reservoir, the plasma flame defining a reaction zone for reacting one or more reactants to produce the high purity silicon.

10. The plasma deposition apparatus for making high purity silicon according to claim 9, further comprising:
one or more auxiliary gas injection ports disposed in the chamber for injecting auxiliary gases into the chamber.

11. The plasma deposition apparatus for making high purity silicon according to claim 10, wherein the one or more auxiliary gas injection ports are disposed at a downward angle toward the product collection reservoir.

12. The plasma deposition apparatus for making high purity silicon according to claim 9, further comprising:
one or more vapor/gas removal ports disposed in the chamber for recovering at least one of un-deposited solids and un-reacted chemicals from the chamber.

13. The plasma deposition apparatus for making high purity silicon according to claim 12, wherein the one or more vapor/gas removal ports are disposed at a downward angle toward the product collection reservoir.

14. The plasma deposition apparatus for making high purity silicon according to claim 9, wherein the one or more induction coupled plasma torches are substantially perpendicular to the product collection reservoir.

15. The plasma deposition apparatus for making high purity silicon according to claim 9, wherein the chamber is made from a material that shields RF energy and isolates the chamber from the environment outside of the chamber.

16. The plasma deposition apparatus for making high purity silicon according to claim 9, wherein the one or more induction coupled plasma torches further comprises:
one or more zinc injection ports for injecting zinc into the plasma flame.

17. A method for collecting liquid or molten high purity silicon in a product collection reservoir in a reaction chamber, comprising:
providing the product collection reservoir;
providing at least one vertically downwardly positioned high frequency induction coupled plasma torch comprising a coil;
introducing a plasma gas consisting essentially of an inert gas into the high frequency induction coupled plasma torch to form a plasma within the coil;
injecting reactants into the high frequency induction coupled plasma torch to produce a high purity silicon; and
collecting the high purity silicon produced by the induction coupled plasma torch in a liquid or molten state into the product collection reservoir.

18. The method for collecting liquid or molten high purity silicon in a product collection reservoir according to claim 17, further comprising:
adjusting the partial pressure within the chamber.

19. The method for collecting liquid or molten high purity silicon in a product collection reservoir according to claim 17, further comprising:
heating the product collection reservoir to keep the high purity silicon in a liquid or molten state.

20. The method for collecting liquid or molten high purity silicon in a product collection reservoir according to claim 17, further comprising:
controlling the temperature of the product collection reservoir.

21. The method for collecting liquid or molten high purity silicon in a product collection reservoir according to claim 17, further comprising:
injecting auxiliary gases into the chamber.

22. The method for collecting liquid or molten high purity silicon in a product collection reservoir according to claim 17, further comprising:
removing at least one of un-deposited solids and un-reacted chemicals from the chamber.

23. The method for collecting liquid or molten high purity silicon in a product collection reservoir according to claim 17, further comprising:
introducing a supply of zinc into the high frequency induction coupled plasma torch.

24. A method for producing a silicon crystal, comprising:
providing a product collection reservoir;
providing at least one vertically downwardly positioned high frequency induction coupled plasma torch comprising a coil;
introducing a plasma gas consisting essentially of an inert gas into the high frequency induction coupled plasma torch to form a plasma within the coil;
injecting reactants into the high frequency induction coupled plasma torch to produce a high purity silicon;
collecting the high purity silicon produced by the induction coupled plasma torch in a liquid or molten state into the product collection reservoir; and
transferring the high purity silicon in a liquid or molten state to a crucible; and
producing the silicon crystal.

25. The method for producing a silicon crystal according to claim 24, further comprising:
storing the high purity silicon in a liquid or molten state prior to transferring it to the crucible.

26. The method for producing a silicon crystal according to claim 24, further comprising:
transferring the high purity silicon in a liquid or molten state in a conduit from the product collection reservoir to the crucible.

27. The method for producing a silicon crystal according to claim 26, further comprising:
heating the conduit to keep the high purity silicon in a liquid or molten state.

28. The method for producing a silicon crystal according to claim 24, further comprising:
introducing a supply of zinc into the high frequency induction coupled plasma torch.

29. The method for producing a silicon crystal according to claim 24, wherein the silicon crystal is a silicon wafer.
